(19) United States
(12) Patent Application Publication
(10) Pub. No.: US 2026/0086136 A1
(43) Pub. Date: Mar. 26, 2026

(54) METHOD FOR DETERMINING MINIMUM NUMBER OF SAMPLES REQUIRED FOR OBTAINING DIELECTRIC BREAKDOWN STRENGTH AND ELECTRONIC DEVICE AND COMPUTER-READABLE STORAGE MEDIUM IMPLEMENTING SAID METHOD

(71) Applicant: HUAZHONG UNIVERSITY OF SCIENCE AND TECHNOLOGY, Hubei (CN)

(72) Inventors: Hua LI, Hubei (CN); Jing LAN, Hubei (CN); Guohao ZHANG, Hubei (CN); Fuchang LIN, Hubei (CN)

(73) Assignee: HUAZHONG UNIVERSITY OF SCIENCE AND TECHNOLOGY, Hubei (CN)

(21) Appl. No.: 19/347,660

(22) Filed: Oct. 1, 2025

Related U.S. Application Data
(63) Continuation of application No. PCT/CN2024/124403, filed on Oct. 12, 2024.

(30) Foreign Application Priority Data
Sep. 25, 2024 (CN) 202411340789.5

(51) Int. Cl. G01R 31/20; G01R 31/12; G01R 31/18

(52) U.S. Cl. CPC G01R 31/20; G01R 31/1272; G01R 31/18

(57) ABSTRACT

The present disclosure discloses a method for determining the minimum number of samples required for obtaining dielectric breakdown strength, belonging to the field of dielectric analysis technology. The method includes: characterizing a current key quantity of each sub-distribution by using a set current experiment sample size, a reliability measure and a reliability estimate of Weibull sub-distributions corresponding to respective breakdown causes to select target sub-distributions; considering a relationship between the current key quantity of the target sub-distributions and a reference value, if the current key quantity is greater than the reference value, then increasing the current experiment sample size until the corresponding current key quantity is less than the reference value, and taking the current experiment sample size as the minimum number of samples.

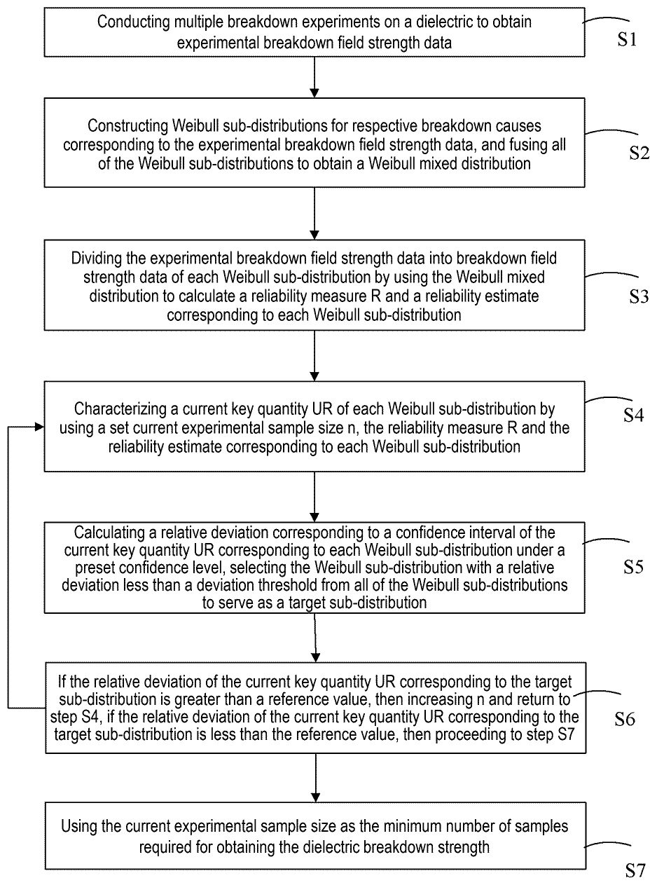

### CROSS-REFERENCE TO RELATED APPLICATION

This application is a continuation of international application of PCT application serial no. PCT/CN2024/124403 filed on Oct. 12, 2024, which claims the priority benefit of China application no. 202411340789.5 filed on Sep. 25, 2024. The entirety of each of the above mentioned patent applications is hereby incorporated by reference herein and made a part of this specification.

The present disclosure belongs to a dielectric analysis technology, and more specifically, relates to a method for determining the minimum number of samples required for obtaining dielectric breakdown strength.

### DESCRIPTION OF RELATED ART

The electrical strength of dielectric materials is an important indicator for measuring the insulation reliability and service life of dielectrics. The electrical strength of dielectric materials represents the highest electric field strength that the material can withstand under the action of an electric field to avoid being damaged (breakdown). The electrical strength is typically expressed as a ratio (in unit of kV/m) of a breakdown voltage value of a test sample to a thickness thereof (an average thickness of a sample between two electrode plates, with a paint film as coating). The breakdown strength values of many polymer insulation materials at liquid nitrogen and liquid helium temperatures do not differ significantly, so the breakdown strength data at liquid nitrogen temperature may also serve as reference for designing electrical equipment operating at liquid helium temperature. Currently, there is no unified standard for breakdown test methods at low temperatures.

In the related art, the dielectric breakdown strength is normally obtained by using breakdown test methods combined with Weibull distribution analysis. In practice, dielectric breakdown normally includes multiple breakdown mechanisms, therefore it is more suitable to utilize breakdown field strength data obtained from multiple groups of breakdown experiments, and utilize the breakdown field strength data to obtain a mixed Weibull distribution model to characterize the breakdown field strength of the dielectric.

However, the minimum number of samples required for obtaining the dielectric breakdown strength is normally determined through empirical values, resulting in low accuracy. Therefore, it is necessary to provide a method for determining the minimum number of samples for dielectric breakdown testing.

### SUMMARY

In view of the above defects or requirements of improving the related art, the present disclosure provides a method for determining a minimum number of samples required for obtaining a dielectric breakdown strength, aiming to solve the technical problem of related art, where insufficient accuracy results from determining the minimum number of samples required for obtaining the dielectric breakdown strength based largely on experiences.

To achieve the above purpose, according to one aspect of the present disclosure, a method for determining the minimum number of samples required for obtaining the dielectric breakdown strength is provided, including:
S1: Conducting multiple breakdown experiments on a dielectric to obtain experimental breakdown field strength data;
S2: Constructing Weibull sub-distributions for respective breakdown causes corresponding to the experimental breakdown field strength data, and superimposing all of the Weibull sub-distributions to obtain a Weibull mixed distribution;
S3: Dividing the experimental breakdown field strength data into breakdown field strength data of each Weibull sub-distribution by using the Weibull mixed distribution to calculate a reliability measure R and a reliability estimate \hat{R} corresponding to each Weibull sub-distribution;
S4: Characterizing a current key quantity U_{R} of each Weibull sub-distribution as

$${U}_{R} = \sqrt{n} [ ln ( \frac{ln R}{ln \hat{R}} ) ]$$

by using a set current experimental sample size n, the reliability measure R and the reliability estimate \hat{R} corresponding to each Weibull sub-distribution;
S5: Calculating a relative deviation corresponding to a confidence interval of the current key quantity U_{R} corresponding to each Weibull sub-distribution under a preset confidence level, selecting the Weibull sub-distribution with a relative deviation less than a deviation threshold from all of the Weibull sub-distributions to serve as a target sub-distribution;
S6: If the relative deviation of the current key quantity U_{R} corresponding to the target sub-distribution is greater than a reference value, then increasing n and return to step S4, if the relative deviation of the current key quantity U_{R} corresponding to the target sub-distribution is less than the reference value, then proceeding to step S7;
S7: Using the current experimental sample size as the minimum number of samples required for obtaining the dielectric breakdown strength.

In an embodiment, the step S2 includes:
S21: Conducting a causal analysis on the experimental breakdown field strength data to identify all of the breakdown causes;
S22: Constructing the Weibull sub-distributions corresponding to respective breakdown causes by using a formula

$${F}_{i} ( E ) = 1 - exp [ - {( \frac{E - {E}_{i min}}{{α}_{i}} )}^{{β}_{i}} ] ,$$

wherein Fᵢ(E) represents a breakdown cumulative probability distribution of a sub-distribution caused by an i-th breakdown cause, αᵢ is a scale parameter caused by the i-th breakdown cause, βᵢ is a shape parameter caused by the i-th breakdown cause, and Eᵢₘᵢₙ is a location parameter caused by the i-th breakdown cause;
S23: Superimposing all of the Weibull sub-distributions to obtain the Weibull mixed distribution.

In an embodiment, the step S23 includes: conducting a proportion-weighted fusion by using a formula

$$F ( E ) = {\sum }_{i = 1}^{N} {m}_{i} {F}_{i} ( E )$$

to obtain the Weibull mixed distribution, wherein mi is a proportion of an i-th Weibull sub-distribution, and N is a total number of the breakdown causes.

In an embodiment, the step S3 includes:
Dividing the experimental breakdown field strength data into the breakdown field strength data of each Weibull sub-distribution by using the Weibull mixed distribution;
Using a standard deviation σ and a mean μ of each Weibull sub-distribution as a coefficient of variation cov corresponding to each Weibull sub-distribution, calculating the reliability measure R by using the coefficient of variation cov corresponding to each Weibull sub-distribution and a percentile of a cumulative breakdown probability;
Calculating the corresponding reliability estimate \hat{R} based on estimated parameters \hat{α} and \hat{β} corresponding to the breakdown field strength data of each Weibull sub-distribution.

In an embodiment, the step S5 includes:
S51: Calculating the confidence interval (U_{RL}, U_{RU}) corresponding to U_{R} corresponding to each sub-distribution at the preset confidence level γ, and using a larger value among the relative deviations corresponding to U_{RL} and U_{RU} respectively as the relative deviation corresponding to each Weibull sub-distribution;
S52: Selecting the Weibull sub-distribution with a relative deviation greater than the deviation threshold from all of the Weibull sub-distributions as the target sub-distribution.

In an embodiment, the step S52 includes: selecting the sub-distribution with a proportion weight greater than a proportion threshold and a relative deviation less than the deviation threshold from all the Weibull sub-distributions as the target sub-distribution.

In an embodiment, the step S52 includes: using the sub-distribution with a smallest relative deviation among all of the Weibull sub-distributions as the target sub-distribution.

In an embodiment, the step S7 includes: if there are multiple target sub-distributions, using the preset current experiment sample size n corresponding to a maximum relative deviation of the current key quantity U_{R} corresponding to the multiple target sub-distributions as the minimum number of samples required for obtaining the dielectric breakdown strength.

According to another aspect of the present disclosure, an electronic device is provided, including a memory and a processor. The memory stores a computer program, and the processor implements the steps of the determining method when executing the computer program.

According to another aspect of the present disclosure, a computer-readable storage medium is provided, on which a computer program is stored, and the computer program implements the steps of the determining method when executed by a processor.

### BRIEF DESCRIPTION OF THE DRAWINGS

FIGURE is a flowchart of a method for determining a minimum number of samples required for obtaining a dielectric breakdown strength provided by Embodiment 1 of the present disclosure.

### DESCRIPTION OF THE EMBODIMENTS

In order to make the objectives, technical schemes and advantages of the present disclosure more comprehensible, the present disclosure will be described in further detail below in combination with the accompanying drawings and embodiments. It should be understood that the specific embodiments described herein are merely used to explain the present disclosure and are not used to limit the present disclosure. In addition, the technical features involved in the various embodiments of the present disclosure described below may be combined with each other as long as they do not conflict with each other.

### Embodiment 1

As shown in FIGURE, the present embodiment provides a method for determining a minimum number of samples required for obtaining a dielectric breakdown strength, including: S1: conducting multiple breakdown experiments on a dielectric to obtain experimental breakdown field strength data; S2: constructing Weibull sub-distributions for respective breakdown causes corresponding to the experimental breakdown field strength data, and superimposing all of the Weibull sub-distributions to obtain a Weibull mixed distribution; S3: dividing the experimental breakdown field strength data into breakdown field strength data of each Weibull sub-distribution by using the Weibull mixed distribution to calculate a reliability measure R and a reliability estimate \hat{R} corresponding to each Weibull sub-distribution; S4: characterizing a current key quantity U_{R} of each Weibull sub-distribution as

$${U}_{R} = \sqrt{n} [ ln ( \frac{ln R}{ln \hat{R}} ) ]$$

by using a set current experimental sample size n, the reliability measure R and the reliability estimate \hat{R} corresponding to each Weibull sub-distribution; S5: calculating a relative deviation corresponding to a confidence interval of the current key quantity U_{R} corresponding to each Weibull sub-distribution under a preset confidence level, selecting the Weibull sub-distribution with a relative deviation less than a deviation threshold from all of the Weibull sub-distributions to serve as a target sub-distribution; S6: if the relative deviation of the current key quantity U_{R} corresponding to the target sub-distribution is greater than a reference value, then increasing n and return to step S4, if the relative deviation of the current key quantity U_{R} corresponding to the target sub-distribution is less than the reference value, then proceeding to step S7; S7: using the current experimental sample size as the minimum number of samples required for obtaining the dielectric breakdown strength.

It should be understood that, although the various steps in the flowchart of FIGURE are shown sequentially as indicated by the arrows, these steps are not necessarily executed sequentially in the order indicated by the arrows. Unless explicitly specified herein, the execution of these steps is not subject to strict sequential limitations, and such steps may be performed in alternative orders. Furthermore, at least a portion of the steps depicted in FIGURE may include multiple sub-steps or multiple phases, wherein said sub-steps or phases are not necessarily executed simultaneously, but may be performed at different times. The execution sequence of such sub-steps or phases is not necessarily in order, but may be executed alternately or in rotation with other steps or with at least a portion of the sub-steps or phases of other steps.

As an alternative implementation method, the step S2 includes: S21: conducting a causal analysis on the experimental breakdown field strength data to identify all breakdown causes; S22: constructing the Weibull sub-distributions corresponding to respective breakdown causes by using a formula

$${F}_{i} ( E ) = 1 - exp [ - {( \frac{E - {E}_{i min}}{{α}_{i}} )}^{{β}_{i}} ] ,$$

wherein Fᵢ(E) represents a breakdown cumulative probability distribution of a sub-distribution caused by an i-th breakdown cause, αᵢ is a scale parameter caused by the i-th breakdown cause, βᵢ is a shape parameter caused by the i-th breakdown cause, and Eᵢₘᵢₙ is a location parameter caused by the i-th breakdown cause; S23: superimposing all of the Weibull sub-distributions to obtain the Weibull mixed distribution.

As an alternative implementation method, the step S23 includes: conducting a proportion-weighted fusion by using a formula

$$F ( E ) = {\sum }_{i = 1}^{N} {m}_{i} {F}_{i} ( E )$$

to obtain the Weibull mixed distribution, wherein m; is a proportion of the i-th Weibull sub-distribution, and N is a total number of breakdown causes.

As an alternative implementation method, the step S3 includes: dividing the experimental breakdown field strength data into breakdown field strength data of each Weibull sub-distribution by using the Weibull mixed distribution; using a standard deviation σ and a mean μ of each Weibull sub-distribution as a coefficient of variation cov corresponding to each Weibull sub-distribution,

$$COV = \frac{σ}{μ} = \frac{\sqrt{Γ ( 1 + \frac{2}{β} ) - {Γ}^{2} ( 1 + \frac{1}{β} )}}{Γ ( 1 + \frac{1}{β} )} , μ = αΓ ( 1 + \frac{1}{β} ) ,$$

wherein the coefficient of variation COV is a ratio of the standard deviation to the mean, and Γ is a gamma function; calculating the reliability measure R by using the coefficient of variation cov corresponding to each Weibull sub-distribution and a percentile of a cumulative breakdown probability; calculating the corresponding reliability estimate \hat{R} based on the estimated parameters \hat{α} and \hat{β} corresponding to the breakdown field strength data of each Weibull sub-distribution. It should be noted that the estimated parameters \hat{α} and \hat{β} satisfy:

$$\{ \begin{matrix}\frac{{\sum }_{i = 1}^{n} {x}_{i}^{\hat{β}} ln ( {x}_{i} )}{{\sum }_{i = 1}^{n} {x}_{i}^{\hat{β}}} - \frac{1}{\hat{β}} - \frac{1}{n} {\sum }_{i = 1}^{n} ln ( {x}_{i} ) = 0 \\ \hat{α} = {( {\sum }_{i = 1}^{n} {x}_{i}^{\hat{β}} / n )}^{\frac{1}{\hat{β}}}\end{matrix} .$$

As an alternative implementation method, the step S5 includes: calculating the confidence interval (U_{RL}, U_{RU}) corresponding to U_{R} corresponding to each sub-distribution at the preset confidence level γ, and using a larger value among the relative deviations corresponding to U_{RL} and U_{RU} respectively as the relative deviation corresponding to each Weibull sub-distribution; S52: selecting the Weibull sub-distribution with a relative deviation greater than the deviation threshold from all of the Weibull sub-distributions as the target sub-distribution. The confidence interval (U_{RL}, U_{RU}) is determined based on the confidence level γ, the percentile p, and the sample size n, while the percentile p is only related to COV, therefore U_{R} is correlated with the coefficient of variation COV of the breakdown data and the sample size n.

Furthermore, a Monte Carlo simulation method is employed to estimate the minimum number of samples of sub-distributions. The input parameters of the Monte Carlo simulation method consist of the coefficient of variation COV of sub-distribution data, the sample size n, the number of simulations, and the confidence level γ, which randomly generate a set of Weibull distribution data with the sample size n that conforms to COV, then a maximum likelihood estimation method is adopted to estimate this set of data to obtain the corresponding U_{R} as one simulation. The number of simulations should not be less than 100000 times. The results of each simulation are counted, and the confidence interval of U_{R} is determined through the confidence level γ, then the corresponding relative deviation Δ is determined through U_{R}. The above steps will yield the relative deviation Δ between the estimate obtained from a set of data under a specific COV and a true value across different sample sizes n, thereby determining the minimum number of samples for the sub-distribution under the specific COV within an acceptable Δ.

As an alternative implementation method, the step S52 includes: selecting the sub-distribution with a proportion weight greater than a proportion threshold and a relative deviation less than the deviation threshold from all the Weibull sub-distributions as the target sub-distribution.

As an alternative implementation method, the step S52 includes: using the sub-distribution with the smallest relative deviation among all of the Weibull sub-distributions as the target sub-distribution.

As an alternative implementation method, the step S7 includes: if there are multiple target sub-distributions, using the preset current experiment sample size n corresponding to the maximum relative deviation of the current key quantity U_{R} corresponding to the multiple target sub-distributions as the minimum number of samples required for obtaining the dielectric breakdown strength.

For example, polypropylene films with uniform thickness d may be used as samples. According to the electrode method recommended by national standard GB T 13542.2-2021 Films for electrical insulation, to measure the breakdown field strength of these samples, it is preset that an initial experiment sample size is 20, the number i of an attribution analysis determines sub-distributions is 3, and a three-parameter Weibull mixed distribution is adopted to fit the experiment data to obtain comprehensive distribution parameters. The COV of breakdown data within the dominant sub-distribution range is 0.33, the confidence level is γ=0.9, the relative deviation Δ is 7%, and the minimum number of samples of the sub-distribution with the largest proportion weight obtained through the Monte Carlo simulation is 60. Therefore, the minimum number of samples of the mixed distribution is 60.

### Embodiment 2

The present embodiment provides an electronic device, including a memory and a processor. The memory stores a computer program, and the processor implements the steps of the determining method when executing the computer program.

### Embodiment 3

The present embodiment provides a computer-readable storage medium, on which a computer program is stored. The computer program implements the steps of the determining method when executed by a processor.

Overall, the above technical schemes conceived by the present disclosure may achieve the following advantageous effects compared with the related art.
(1) The present disclosure provides a method for determining the minimum number of samples required for obtaining the dielectric breakdown strength. In the method, the set current experiment sample size n, the reliability measure R and the reliability estimate R corresponding to the Weibull sub-distributions of each breakdown cause are utilized to characterize the current key quantity U_{R} of each Weibull sub-distribution; the target sub-distribution is selected according to the relative deviation corresponding to the current key quantity U_{R} corresponding to each Weibull sub-distribution; the relationship between the current key quantity U_{R} of the target sub-distribution and the reference value is taken into consideration, if the current key quantity U_{R} is greater than the reference value, then the current experiment sample size n is increased until the current key quantity U_{R} corresponding to the target sub-distribution is less the reference value, and then the current experiment sample size n is used as the minimum number of samples required for obtaining the dielectric breakdown strength. The method of determining the minimum number of samples provided by the present disclosure may take into account the variation patterns of multiple breakdown causes to design the current key quantity U_{R} related to the current experiment sample size n, combine the relationship between the current key quantity U_{R} and the reference value to dynamically adjust the current experiment sample size n, and finally determine the minimum number of samples quickly and accurately. Furthermore, the mixed Weibull distribution model obtained by conducting dielectric breakdown experiments with this minimum number of samples may accurately characterize the breakdown field strength of the dielectric.
(2) This scheme uses the formula

$${F}_{i} ( E ) = 1 - exp [ - {( \frac{E - {E}_{i min}}{{α}_{i}} )}^{{β}_{i}} ]$$

to construct the Weibull sub-distributions corresponding to each of the breakdown causes. Compared with the related art, the present disclosure takes into consideration the minimum breakdown field strength of the dielectric, and the advantage lies in realization of accurate mathematical description of dielectric breakdown characteristics.
(3) This scheme uses the formula

$$F ( E ) = {\sum }_{i = 1}^{N} {m}_{i} {F}_{i} ( E )$$

to conduct the proportion-weighted fusion to obtain the Weibull mixed distribution. Compared with the related art, the present disclosure takes into consideration multiple breakdown causes of the dielectric, and the advantage lies in realization of mechanism-data joint-driven model construction of the dielectric breakdown characteristics.
(4) In this scheme, the standard deviation σ and the mean μ of each Weibull sub-distribution are used as the coefficient of variation cov corresponding to each Weibull sub-distribution; the reliability measure R is calculated by using the coefficient of variation cov corresponding to each Weibull sub-distribution and the percentile of the cumulative breakdown probability; and the relationship between standard statistical parameters and distribution parameters is considered. The advantage lies in realization of the correspondence between Weibull distribution parameters and data dispersion.
(5) In this scheme, the larger value among the relative deviations corresponding to U_{RL} and U_{RU} respectively is used as the relative deviation corresponding to each Weibull sub-distribution; and the possible maximum relative error of parameter estimates is considered. The advantage lies in realization of effective control of estimate deviation.
(6) In this scheme, the sub-distribution with the proportion weight greater than the proportion threshold and the relative deviation less the deviation threshold is selected from all of the Weibull sub-distributions as the target sub-distribution; and the dominance of sub-distributions corresponding to the respective breakdown causes is considered. The advantage lies in realization of reasonable calculation of the required minimum number of samples that conforms to the breakdown mechanism.
(7) In this scheme, the sub-distribution with a smallest relative deviation among all of the Weibull sub-distributions is used as the target sub-distribution; and the achievability of engineering practice is considered. The advantage lies in realization of reasonable reduction of the minimum number of samples for experiments, which is more conducive to engineering applications.
(8) In this scheme, if there are multiple target sub-distributions, the preset current experiment sample size n corresponding to a maximum relative deviation of the current key quantity U_{R} corresponding to the multiple target sub-distributions is used as the minimum number of samples required for obtaining the dielectric breakdown strength; and the maximum relative deviation acceptable in engineering practice is considered. The advantage lies in realization of accurate calculation of the minimum number of samples for experiments, which is more conducive to adjustment in combination with engineering practice.

Those skilled in the art can easily understand that the above descriptions are only preferred embodiments of the present disclosure and are not intended to limit the present disclosure. Any modifications, equivalent substitutions and improvements made within the spirit and principles of the present disclosure shall be included within the scope to be protected by the present disclosure.

What is claimed is:

1. A method for determining a minimum number of samples required for obtaining a dielectric breakdown strength, comprising:
S1: conducting a plurality of breakdown experiments on a dielectric to obtain experimental breakdown field strength data;
S2: constructing Weibull sub-distributions for respective breakdown causes corresponding to the experimental breakdown field strength data, and superimposing all of the Weibull sub-distributions to obtain a Weibull mixed distribution;
S3: dividing the experimental breakdown field strength data into breakdown field strength data of each of the Weibull sub-distributions by using the Weibull mixed distribution to calculate a reliability measure R and a reliability estimate \hat{R} corresponding to each of the Weibull sub-distributions;
S4: characterizing a current key quantity U_{R} of each of the Weibull sub-distributions as
$${U}_{R} = \sqrt{n} [ ln ( \frac{ln R}{ln \hat{R}} ) ]$$
by using a set current experimental sample size n, the reliability measure R and the reliability estimate \hat{R} corresponding to each of the Weibull sub-distributions;
S5: calculating a relative deviation corresponding to a confidence interval of the current key quantity U_{R} corresponding to each of the Weibull sub-distributions under a preset confidence level, selecting the Weibull sub-distribution with a relative deviation less than a deviation threshold from all of the Weibull sub-distributions to serve as a target sub-distribution;
S6: if the relative deviation of the current key quantity U_{R} corresponding to the target sub-distribution is greater than a reference value, then increasing n and return to step S4, if the relative deviation of the current key quantity U_{R} corresponding to the target sub-distribution is less than the reference value, then proceeding to step S7;
S7: using the current experimental sample size as the minimum number of the samples required for obtaining the dielectric breakdown strength.

2. The method for determining the minimum number of the samples required for obtaining the dielectric breakdown strength according to claim 1, wherein the step S2 comprises:
S21: conducting a causal analysis on the experimental breakdown field strength data to identify all of the breakdown causes;
S22: constructing the Weibull sub-distributions corresponding to the respective breakdown causes by using a formula
$${F}_{ι} ( E ) = 1 - exp [ - {( \frac{E - {E}_{i min}}{{α}_{t}} )}^{{β}_{i}} ] ,$$
wherein Fᵢ(E) represents a breakdown cumulative probability distribution of a sub-distribution caused by an i-th breakdown cause, αᵢ is a scale parameter caused by the i-th breakdown cause, βᵢ is a shape parameter caused by the i-th breakdown cause, and Eᵢₘᵢₙ is a location parameter caused by the i-th breakdown cause;
S23: superimposing all of the Weibull sub-distributions to obtain the Weibull mixed distribution.

3. The method for determining the minimum number of the samples required for obtaining the dielectric breakdown strength according to claim 2, wherein the step S23 comprises: conducting a proportion-weighted fusion by using a formula
$$F ( E ) = {\sum }_{i = 1}^{N} {m}_{i} {F}_{i} ( E )$$
to obtain the Weibull mixed distribution, wherein mi is a proportion of an i-th Weibull sub-distribution, and N is a total number of the breakdown causes.

4. The method for determining the minimum number of the samples required for obtaining the dielectric breakdown strength according to claim 1, wherein the step S3 comprises:
dividing the experimental breakdown field strength data into the breakdown field strength data of each of the Weibull sub-distributions by using the Weibull mixed distribution;
using a standard deviation σ and a mean μ of each of the Weibull sub-distributions as a coefficient of variation cov corresponding to each of the Weibull sub-distributions, calculating the reliability measure R by using the coefficient of variation cov corresponding to each of the Weibull sub-distributions and a percentile of a cumulative breakdown probability; and
calculating the corresponding reliability estimate \hat{R} based on estimated parameters \hat{α} and \hat{β} corresponding to the breakdown field strength data of each of the Weibull sub-distributions.

5. The method for determining the minimum number of the samples required for obtaining the dielectric breakdown strength according to claim 1, wherein the step S5 comprises:
S51: calculating the confidence interval (U_{RL}, U_{RU}) corresponding to U_{R} corresponding to each sub-distribution at the preset confidence level γ, and using a larger value among the relative deviations corresponding to U_{RL} and U_{RU} respectively as the relative deviation corresponding to each of the Weibull sub-distributions;
S52: selecting the Weibull sub-distribution with a relative deviation greater than the deviation threshold from all of the Weibull sub-distributions as the target sub-distribution.

6. The method for determining the minimum number of the samples required for obtaining the dielectric breakdown strength according to claim 5, wherein the step S52 comprises:
selecting the sub-distribution with a proportion weight greater than a proportion threshold and a relative deviation less than the deviation threshold from all the Weibull sub-distributions as the target sub-distribution.

7. The method for determining the minimum number of the samples required for obtaining the dielectric breakdown strength according to claim 5, wherein the step S52 comprises: using the sub-distribution with a smallest relative deviation among all of the Weibull sub-distributions as the target sub-distribution.

8. The method for determining the minimum number of the samples required for obtaining the dielectric breakdown strength according to claim 6, wherein the step S7 comprises:
if there are a plurality of the target sub-distributions, using the preset current experiment sample size n corresponding to a maximum relative deviation of the current key quantity U_{R} corresponding to the plurality of target sub-distributions as the minimum number of the samples required for obtaining the dielectric breakdown strength.

9. The method for determining the minimum number of the samples required for obtaining the dielectric breakdown strength according to claim 7, wherein the step S7 comprises:
if there are a plurality of the target sub-distributions, using the preset current experiment sample size n corresponding to a maximum relative deviation of the current key quantity U_{R} corresponding to the plurality of target sub-distributions as the minimum number of the samples required for obtaining the dielectric breakdown strength.

10. An electronic device, comprising a memory and a processor, the memory storing a computer program, and the processor implements the steps of the method according to claim 1 when executing the computer program.

11. An electronic device, comprising a memory and a processor, the memory storing a computer program, and the processor implements the steps of the method according to claim 2 when executing the computer program.

12. An electronic device, comprising a memory and a processor, the memory storing a computer program, and the processor implements the steps of the method according to claim 3 when executing the computer program.

13. An electronic device, comprising a memory and a processor, the memory storing a computer program, and the processor implements the steps of the method according to claim 4 when executing the computer program.

14. An electronic device, comprising a memory and a processor, the memory storing a computer program, and the processor implements the steps of the method according to claim 5 when executing the computer program.

15. An electronic device, comprising a memory and a processor, the memory storing a computer program, and the processor implements the steps of the method according to claim 6 when executing the computer program.

16. An electronic device, comprising a memory and a processor, the memory storing a computer program, and the processor implements the steps of the method according to claim 7 when executing the computer program.

17. An electronic device, comprising a memory and a processor, the memory storing a computer program, and the processor implements the steps of the method according to claim 8 when executing the computer program.

18. An electronic device, comprising a memory and a processor, the memory storing a computer program, and the processor implements the steps of the method according to claim 9 when executing the computer program.

19. A computer-readable storage medium, on which a computer program is stored, and the computer program implements the steps of the method according to claim 1 when executed by a processor.

20. A computer-readable storage medium, on which a computer program is stored, and the computer program implements the steps of the method according to claim 2 when executed by a processor.
